(19) United States
(12) Patent Application Publication
(10) Pub. No.: US 2015/0003907 A1
(43) Pub. Date: Jan. 1, 2015

(54) Device for connecting portable electronic devices to cameras

(71) Applicant: Jeffrey Overall, Fountain Valley, CA (US)

(72) Inventor: Jeffrey Overall, Fountain Valley, CA (US)

(21) Appl. No.: 14/121,046

(22) Filed: Jul. 23, 2014

(51) Int. Cl. H04M 1/02; H05K 5/02

(52) U.S. Cl. CPC H04M 1/0264; H05K 5/0204; H05K 5/0217
USPC 403/408.1

(57) ABSTRACT

The present invention generally relates to devices and methods for attaching cameras, such as the GoPro® camera, to a portable electronic device (“PED”). In one aspect, the present invention is directed to a device for attaching a camera to a portable electronic device. The device comprises a camera mount, a proximal frame, and a distal frame. The camera mount comprises three prong-like protrusions having through-holes, and the camera mount is molded as a unitary piece with the proximal frame.

### FIELD OF THE INVENTION

The present invention generally relates to devices and methods for attaching cameras, such as the GoPro® camera, to a portable electronic device (“PED”).

### BACKGROUND OF THE INVENTION

There has been research and development directed to mobile phone cases. For instance, U.S. Pat. No. 7,609,512 is allegedly directed to the following: “A protective enclosure for an electronic device such as a laptop computer or tablet computer that comprises a shell that is capable of enclosing and substantially surrounding the electronic device. The shell is substantially watertight, substantially rigid and substantially crush-resistant. The inside of the shell has a hook and loop liner with shock absorbing corner bumpers having hook and loop type bases so that the bumpers may attach at any point on the liner inside the shell to accommodate electronic devices of various sizes and to secure the device inside the enclosure in a shock absorbent suspended manner. The shell may further comprise a USB connector hub for connection to the USB port of a laptop computer or PC tablet enclosed in the protective shell.” Abstract.

Despite research and development in this area, there is still a need in the art for new devices and methods for attaching cameras to portable electronic devices.

### BRIEF DESCRIPTION OF THE DRAWINGS

FIG. 1 shows a front view of one embodiment of a device according to the present invention.

FIG. 2 shows a back view of one embodiment of a device according to the present invention.

FIG. 3 shows a bottom view of one embodiment of a device according to the present invention.

FIG. 4 shows a top view of one embodiment of a device according to the present invention.

FIG. 5 shows a front view of one embodiment of a device according to the present invention, where a camera is attached to the device.

FIG. 6 shows a front view of a second embodiment of a device according to the present invention.

FIG. 7 shows a back view of the second embodiment of device according to the present invention.

FIG. 8 shows a bottom view of the second embodiment of the device according to the present invention.

FIG. 9 shows a top view of the second embodiment of the device according to the present invention.

FIG. 10 shows a front view of the second embodiment of a device according to the present invention, where a camera is attached to the device.

FIG. 11 shows a front view of a third embodiment of a device according to the present invention.

FIG. 12 shows a back view of the third embodiment of device according to the present invention.

FIG. 13 shows a bottom view of the third embodiment of the device according to the present invention.

FIG. 14 shows a top view of the third embodiment of the device according to the present invention.

FIG. 15′ shows a front view of the third embodiment of a device according to the present invention, where a camera is attached to the device.

FIG. 16 shows a back view of a device according to the present invention, where a support member has been added along the back of the device.

FIG. 17 shows a device according to FIG. 1, where the device surrounds the smart phone.

FIG. 18 shows a device according to FIG. 6, where the device surrounds the smart phone.

FIG. 19 shows a device according to FIG. 11, where the device surrounds the smart phone.

### SUMMARY OF THE INVENTION

In one aspect, the present invention is directed to a device for attaching a camera to a portable electronic device. The device comprises a camera mount, a proximal frame, and a distal frame. The camera mount comprises three prong-like protrusions having through-holes, and the camera mount is molded as a unitary piece with the proximal frame.

In another aspect, the present invention is directed to a device for attaching a camera to a portable electronic device. The device comprises a camera mount and a frame. The camera mount comprises three prong-like protrusions having through-holes, and the camera mount is molded as a unitary piece with the frame.

### DETAILED DESCRIPTION OF THE INVENTION

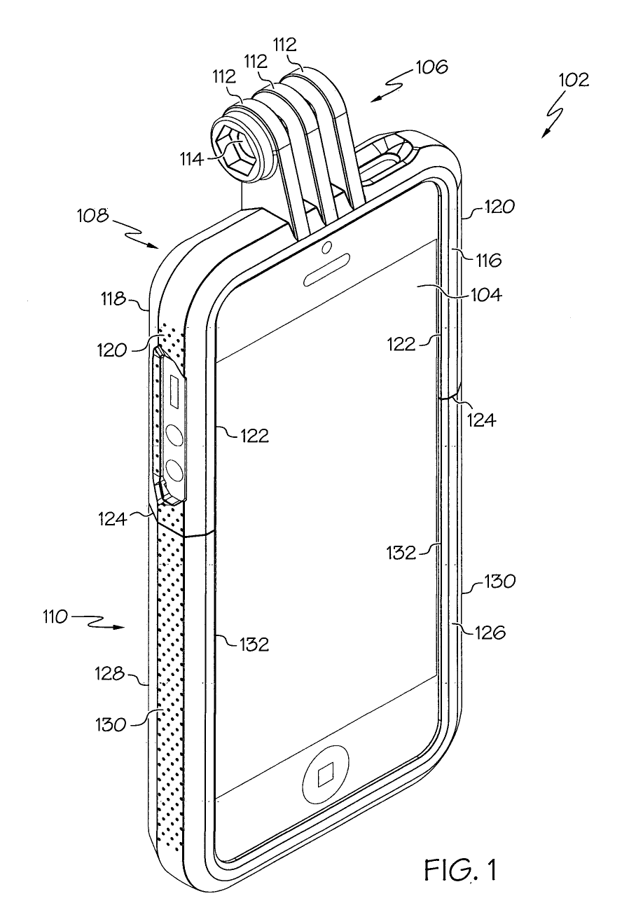

FIG. 1 shows a front view of one embodiment of a device (102) according to the present invention, which surrounds a smart phone (104, iPhone as shown). The device comprises a camera mount (106) attached to a proximal frame (108), and a distal frame (110). Camera mount 106 typically includes three prong-like protrusions (112), each including a through-hole (114). The camera mount 106 is typically molded as a single piece with proximal frame 108, although in certain cases it may be detachable. Proximal frame 108 further comprises a front (116), a back (118) and two sides (120). Front side 116 includes an edge (122) that wraps around smart phone 104, covering a small portion of the smart phone's face. Edge 122 is typically less than 7 mm in width and oftentimes less than 6 mm or 5 mm in width.

Proximal frame 108 is made to connect with distal frame 110 such that a single seam (124) appears around the outside portion of the device. The connection may be of any suitable type known to those of ordinary skill in the art. Distal frame 110 comprises a front (126), a back (128) and two sides (130). Front side 126 includes an edge (132) that wraps around smart phone 104, covering a small portion of the smart phone's face. Edge 132 is typically less than 7 mm in width and oftentimes less than 6 mm or 5 mm in width, but is of the same width as edge 122.

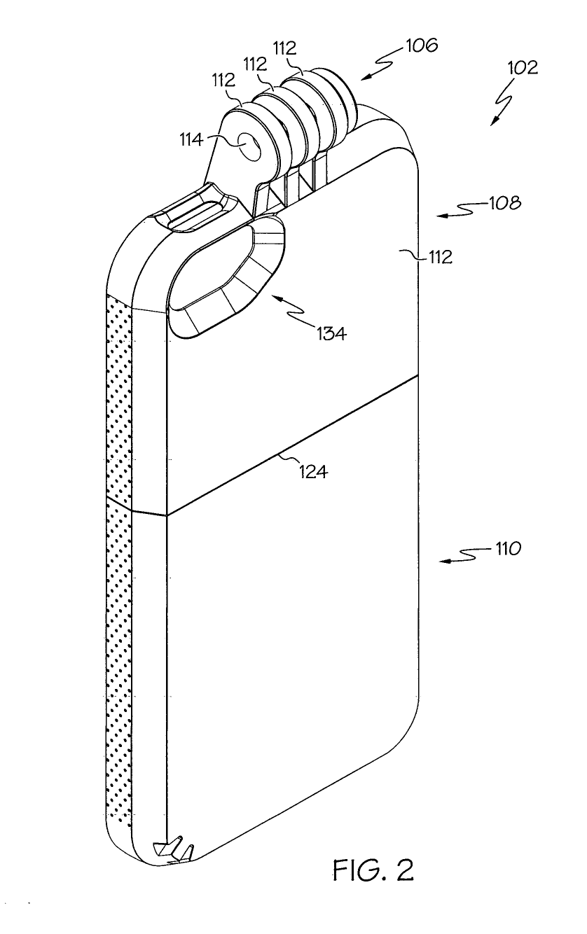

FIG. 2 shows a back (112) of one embodiment of a device (102) according to the present invention, which surrounds a smart phone (104, not shown). Camera mount 106, including protrusions 112 and through-holes 114, is attached to proximal frame 108, which is connected to distal frame 110. Proximal frame 108 optionally includes a cutout portion for a camera lens (134) and connects to distal frame 110, as noted above. Single seam 124 appears between proximal frame 108 and distal frame 110.

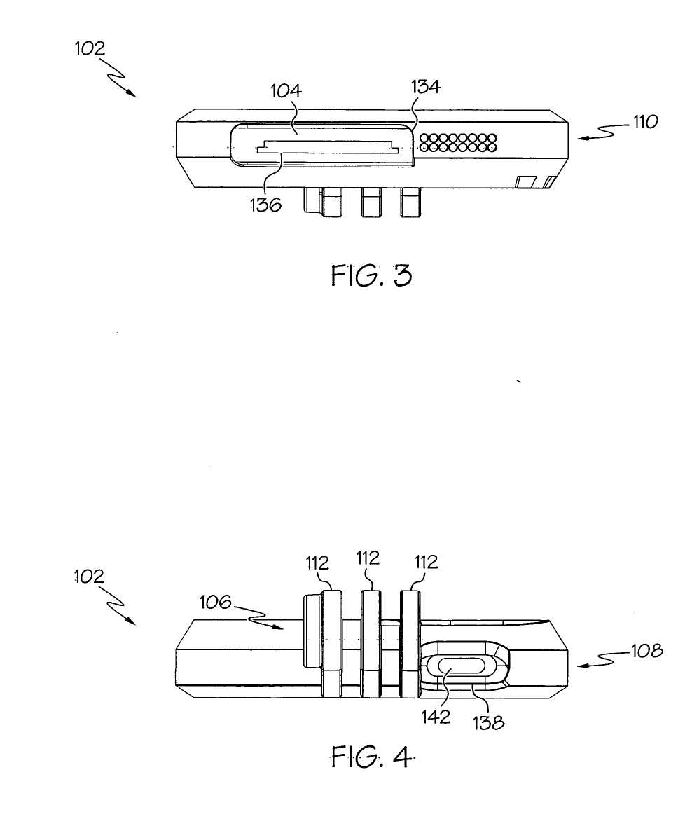

FIG. 3 shows a bottom view of one embodiment of the device 102 surrounding smartphone 104. The figure shows an optional cut-out (134) from the bottom of distal frame 110. Through cut-out 134 is shown the charging receptacle (136) for the smart phone.

FIG. 4 shows a top view of one embodiment of the device 102 surrounding smartphone 104. The figure shows camera mount 106, including protrusions 112. Optional cut-out 138 is shown from the top of proximal frame 108. Through cut-out 138 is shown the on/off button (142) for the smart phone.

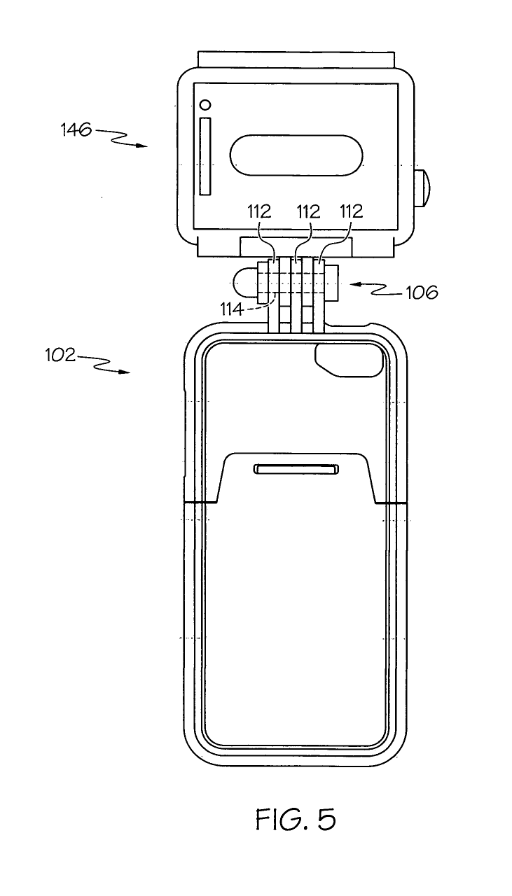

FIG. 5 shows a front view of camera (146) attached to mount 106 of device 102 by passage of a pin into through-holes 114 of protrusions 112.

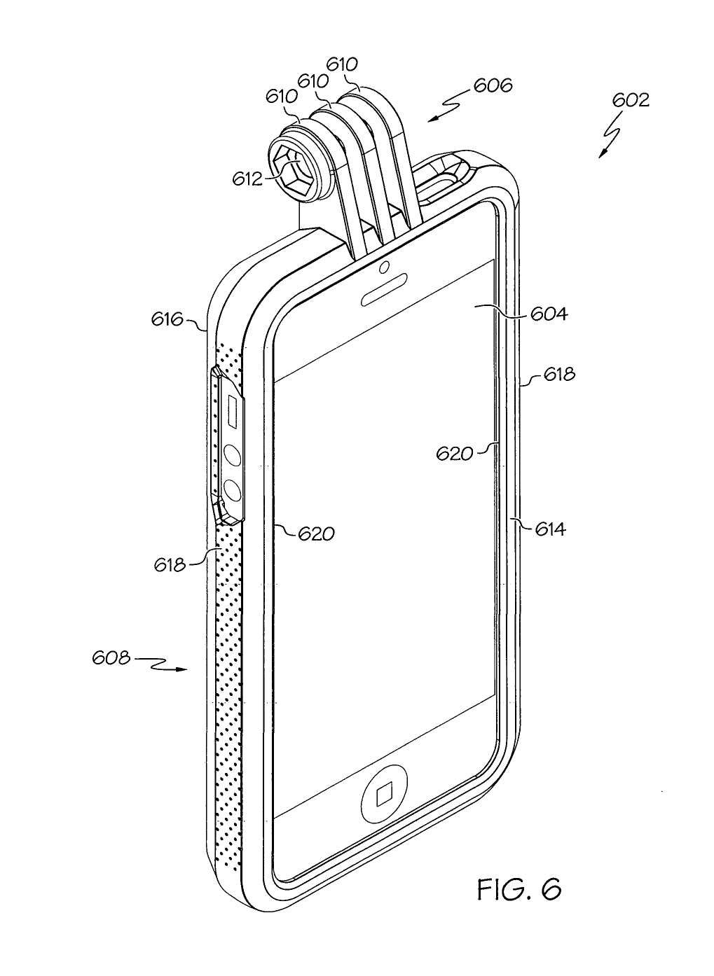

FIG. 6 shows a front view of a second embodiment of a device (602) according to the present invention, which surrounds a smart phone (604, iPhone as shown). The device comprises a camera mount (606) attached to a unitary frame (608). Camera mount 606 typically includes three prong-like protrusions (610), each including a through-hole (612). The camera mount 606 is typically molded as a single piece with frame 608, although in certain cases it may be detachable. Frame 608 further comprises a front (614), a back (616) and two sides (618). Front side 614 includes an edge (620) that wraps around smart phone 604, covering a small portion of the smart phone's face. Edge 620 is typically less than 7 mm in width and oftentimes less than 6 mm or 5 mm in width.

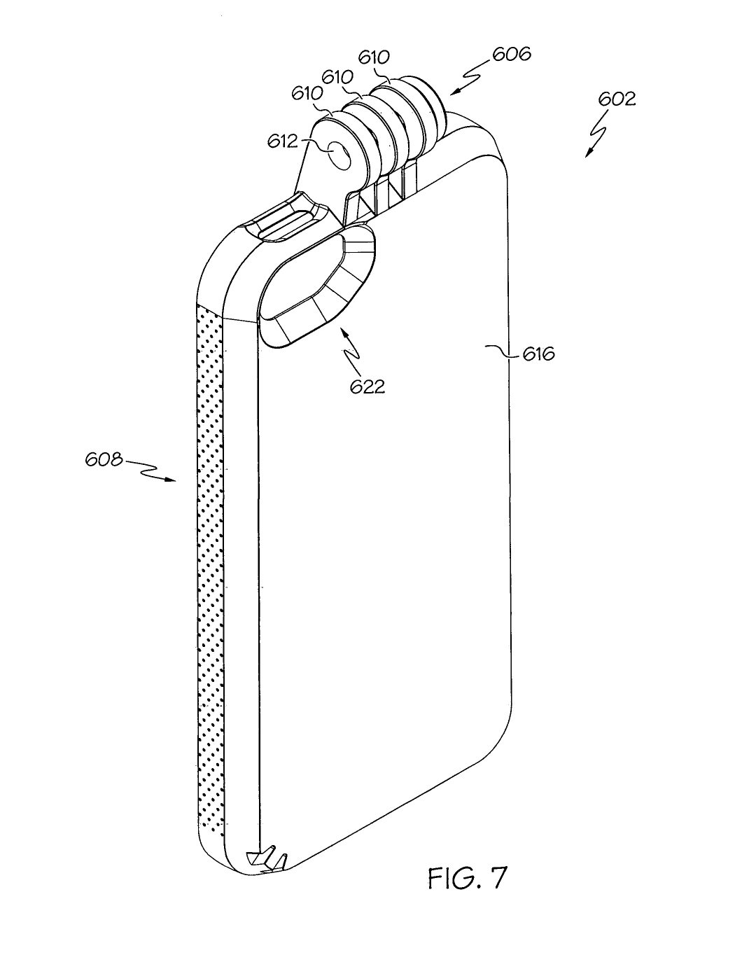

FIG. 7 shows a back (616) of the second embodiment of device 602, which surrounds a smart phone (604, not shown). Camera mount 606, including protrusions 610 and through-holes 612, is attached to frame 608. Frame 608 optionally includes a cutout portion for a camera lens (622).

FIG. 8 shows a bottom view of the second embodiment of the device 602 surrounding smartphone 604. The figure shows an optional cut-out (624) from the bottom of frame 608. Through cut-out 624 is shown the charging receptacle (626) for the smart phone.

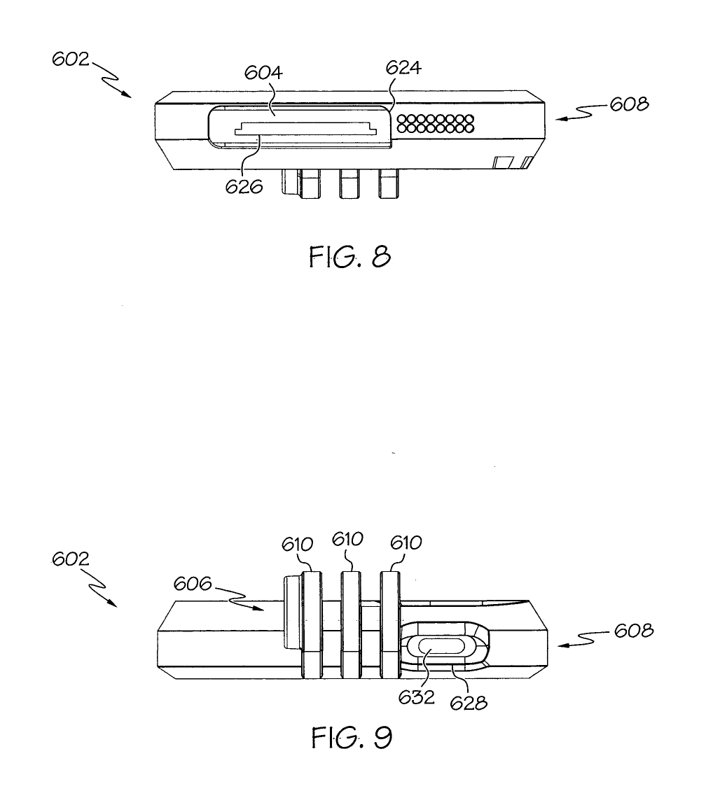

FIG. 9 shows a top view of the second embodiment of the device 602 surrounding smartphone 604. The figure shows camera mount 606, including protrusions 610. Optional cut-out 628 is shown from the top of frame 608. Through cut-out 628 is shown the on/off button (632) for the smart phone.

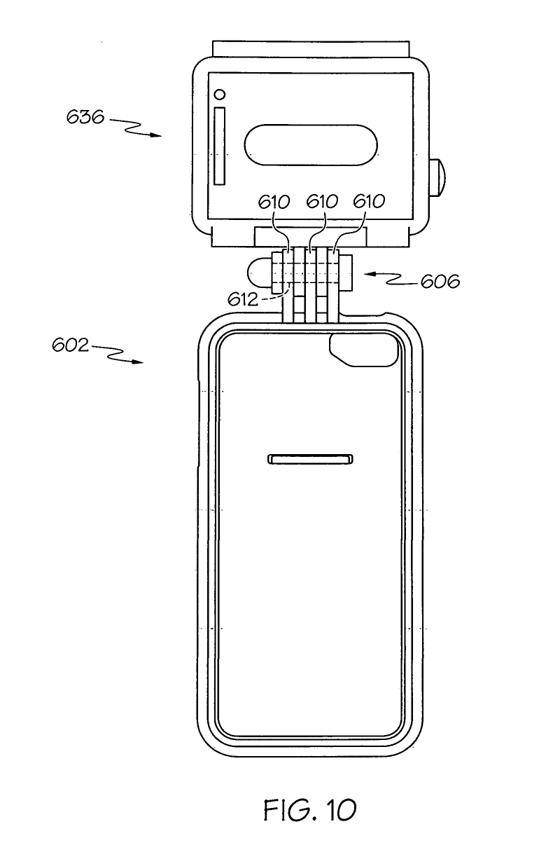

FIG. 10 shows a front view of camera (636) attached to mount 606 of device 602 by passage of a pin into through-holes 612 of protrusions 610.

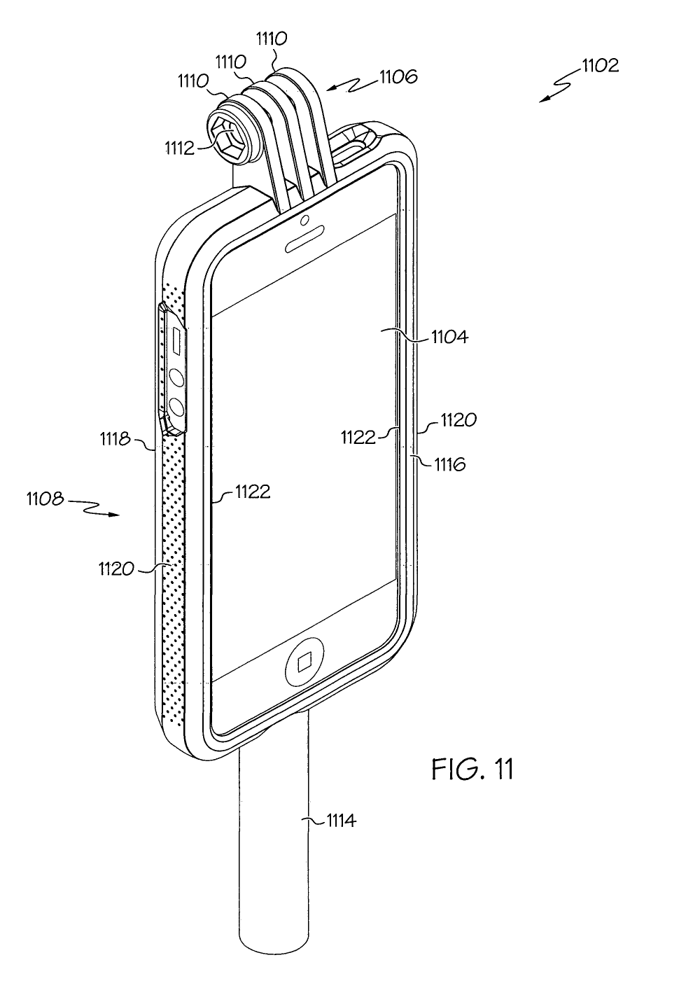

FIG. 11 shows a front view of a third embodiment of a device (1102) according to the present invention, which surrounds a smart phone (1104, iPhone as shown). The device comprises a camera mount (1106) attached to a frame (1108). Camera mount 1106 typically includes three prong-like protrusions (1110), each including a through-hole (1112). The camera mount 1106 is typically molded as a single piece with frame 1108, although in certain cases it may be detachable. Frame 1108 further comprises at least one handle (1114), a front (1116), a back (1118) and two sides (1120). At least one handle 1114 may be of any suitable configuration. As shown it is molded in a single piece along with frame 1108. Front side 1116 includes an edge (1122) that wraps around smart phone 1104, covering a small portion of the smart phone's face. Edge 1122 is typically less than 7 mm in width and oftentimes less than 6 mm or 5 mm in width.

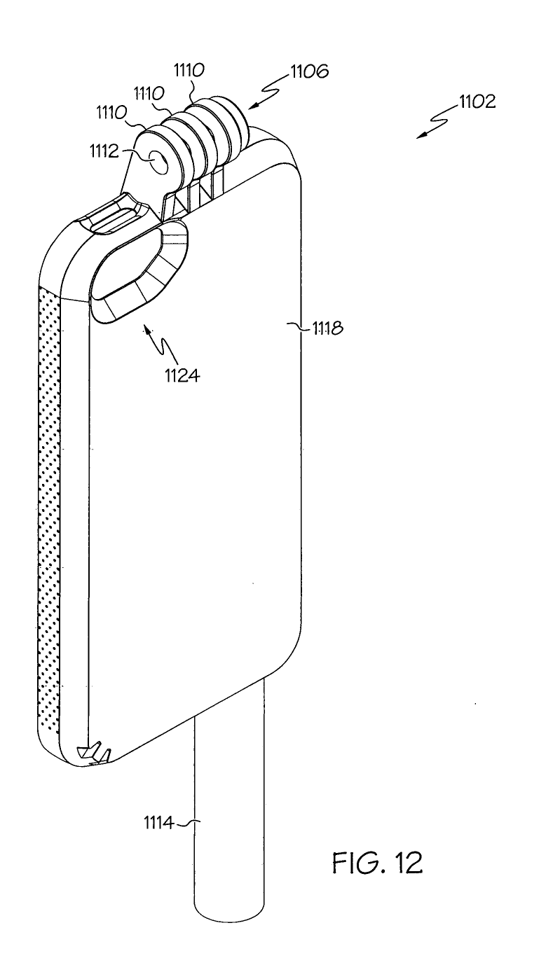

FIG. 12 shows a back 1118 of the third embodiment of device 1102, which surrounds smart phone 1104 (not shown). Camera mount 1106, including protrusions 1110 and through-holes 1112, is connected to frame 1108, as well as handles 1114. Frame 1108 optionally includes a cutout portion for camera lens (1124).

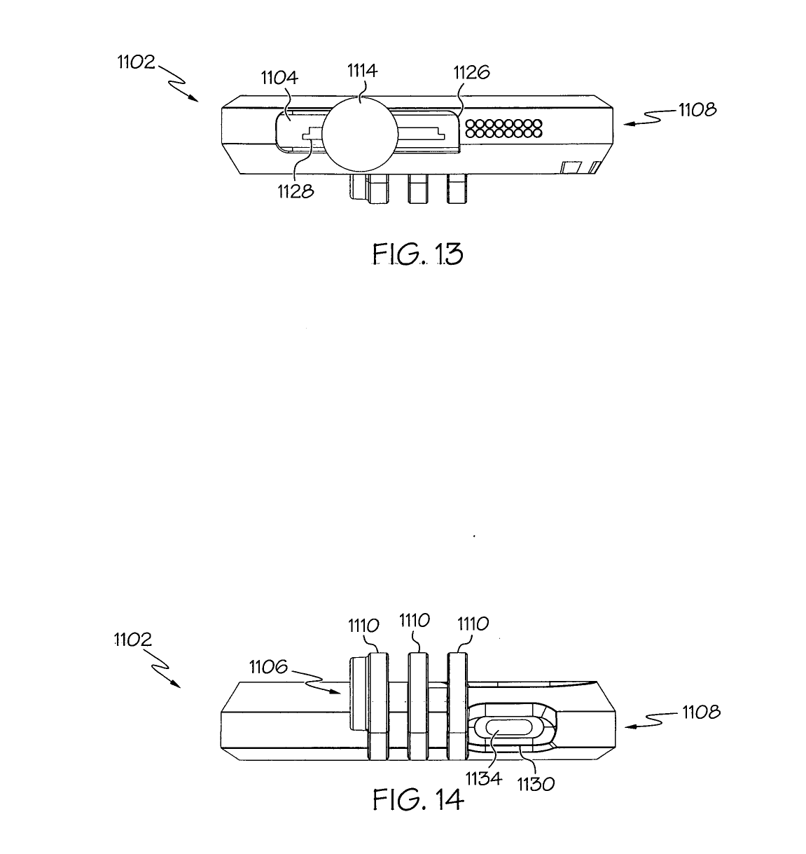

FIG. 13 shows a bottom view of the third embodiment of the device 1102 surrounding smartphone 1104. The figure shows at least one handle 1114 and an optional cut-out (1126) from the bottom of frame 1108. Through cut-out 1126 is shown the charging receptacle (1128) for the smart phone.

FIG. 14 shows a top view of the third embodiment of the device 1102 surrounding smartphone 1104. The figure shows camera mount 1106, including protrusions 1110. Optional cut-out 1130 is shown from the top of frame 1108. Through cut-out 1130 is shown the on/off button (1134) for the smart phone.

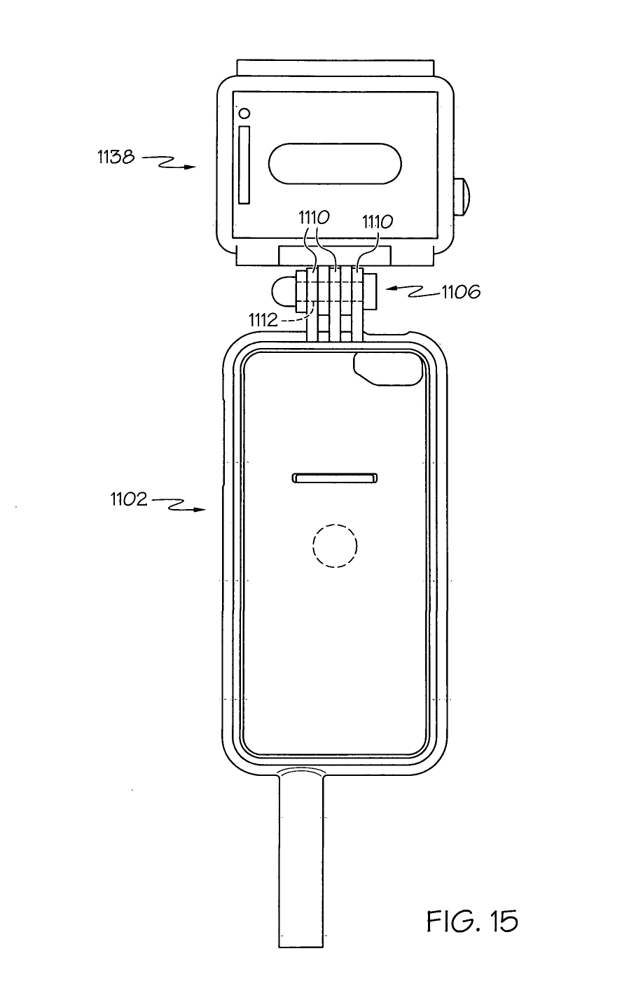

FIG. 15 shows a front view of camera (1138) attached to mount 1106 of device 1102 by passage of a pin into through-holes 1112 of protrusions 1110.

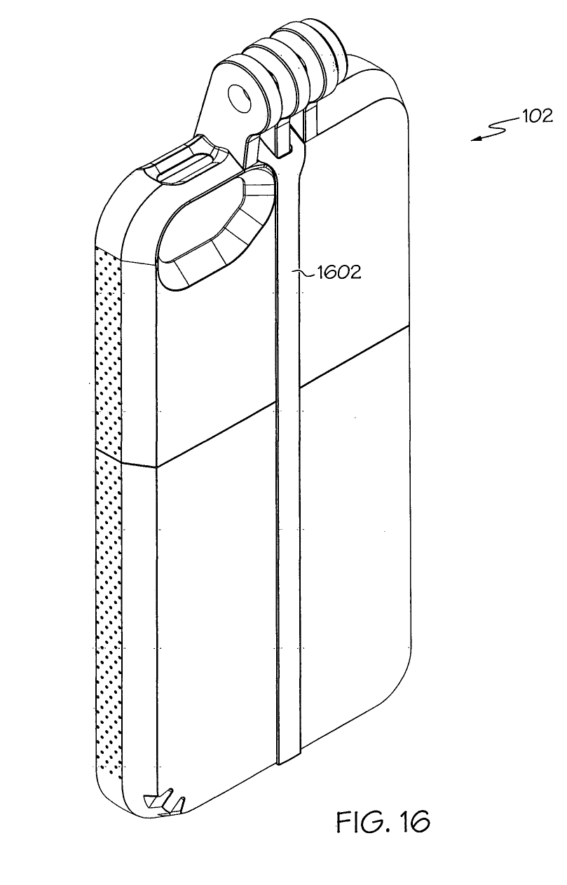

FIG. 16 shows a back view of device 102, surrounding smart phone 104 (not shown), where a support member (1602) has been added along the back of the device. The support member strengthens the device to augment the ability of the device to retain its shape after a camera is attached to the device. It is typically made of a relatively strong material, such as metal, that is usually less than 10 mm in width. Oftentimes, it is less than 9 mm, 8 mm, 6 mm or 5 mm in width.

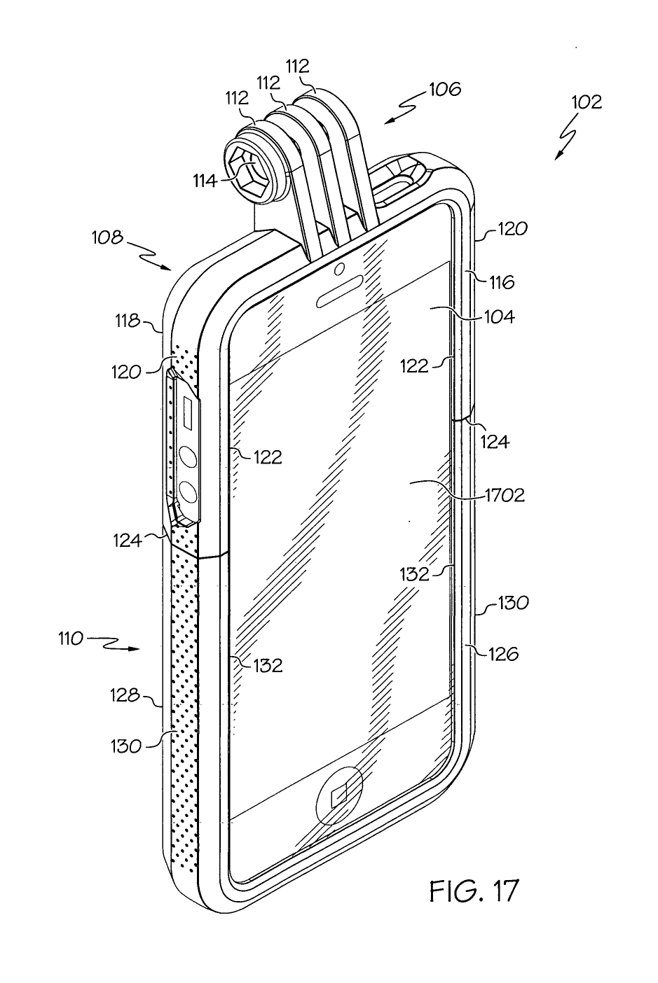

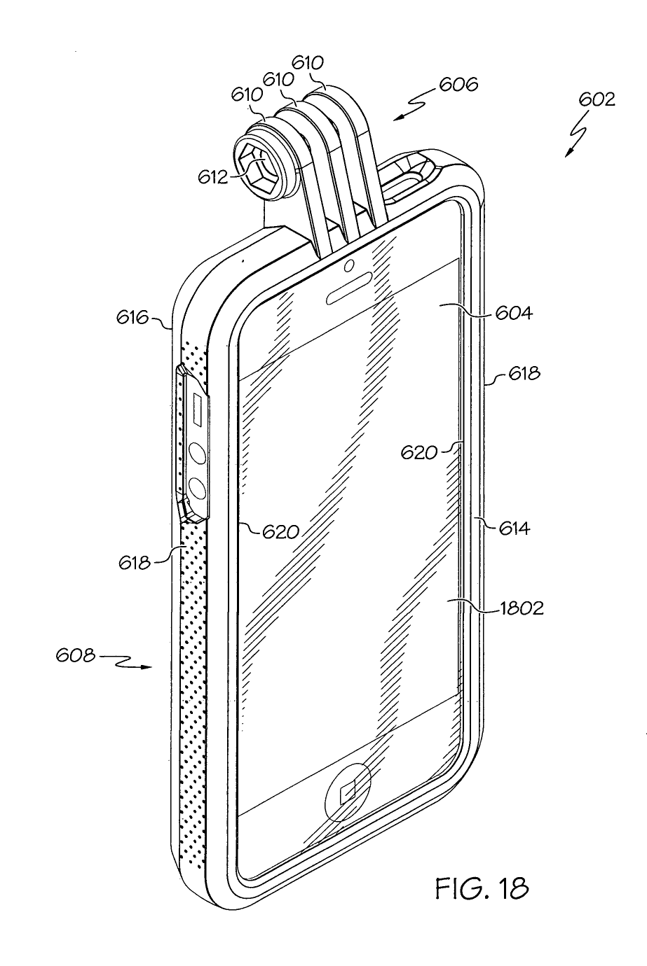

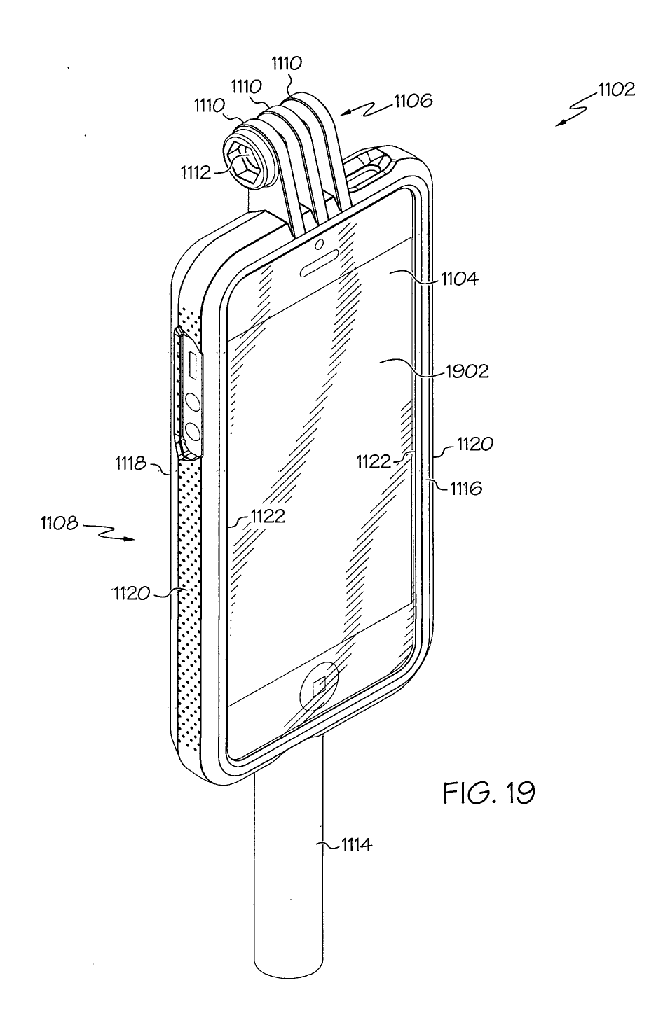

In certain aspects, the device of the present invention completely surrounds the smart phone. FIG. 17 is such a device related to the one shown in FIG. 1, where side 1702 extends from edges 122 to 132. FIG. 18 is such a device related to the one shown in FIG. 6, where side 1802 extends from and to edges 620. FIG. 19 is such a device related to the one shown in FIG. 11, where side 1902 extends from and to edges 1122. The side of the various figures—e.g., 1702, 1802, 1902—may be transparent or opaque.

In one case, the device according to the present invention is made of, or substantially made of, polycarbonate or polyurethane. In another case, the device according to the present invention is made of, or substantially made of, rubber or wood. Any suitable method may be used for construction of the device.

1. A device for attaching a camera to a portable electronic device, wherein the device comprises a camera mount, a proximal frame, and a distal frame, wherein the camera mount comprises three prong-like protrusions having through-holes, and wherein the camera mount is molded as a unitary piece with the proximal frame.

2. The device according to claim 1, wherein the proximal and distal frames have front sides, and wherein the front sides of the proximal and distal frames comprise an edge that wraps around the portable electronic device.

3. The device according to claim 1, wherein the proximal frame connects with the distal frame such that a single seam appears around the outside portion of the device.

4. The device according to claim 1, wherein the proximal frame has a back, and wherein the back of the proximal frame comprises a cutout portion for a camera lens of the portable electronic device.

5. The device according to claim 1, wherein the distal frame has a bottom, and wherein the bottom of the distal frame comprises a cutout portion for a charging receptacle of the portable electronic device.

6. The device according to claim 1, wherein the proximal frame has a top, and wherein the top of the proximal frame comprises a cutout portion for an on/off switch of the portable electronic device.

7. The device according to claim 1, wherein the device comprises at least one handle.

8. The device according to claim 2, wherein the proximal frame connects with the distal frame such that a single seam appears around the outside portion of the device, wherein the proximal frame has a back, and wherein the back of the proximal frame comprises a cutout portion for a camera lens of the portable electronic device, wherein the distal frame has a bottom, and wherein the bottom of the distal frame comprises a cutout portion for a charging receptacle of the portable electronic device, wherein the proximal frame has a top, and wherein the top of the proximal frame comprises a cutout portion for an on/off switch of the portable electronic device, and wherein the edge is less than 7 mm in width.

9. The device according to claim 8, wherein the device comprises at least one handle.

10. A device for attaching a camera to a portable electronic device, Wherein the device comprises a camera mount and a frame, wherein the camera mount comprises three prong-like protrusions having through-holes, and wherein the camera mount is molded as a unitary piece with the frame.

11. The device according to claim 10, wherein the frame has a front side, and wherein the front side of the frame comprises an edge that wraps around the portable electronic device.

12. The device according to claim 10, wherein the frame has a back, and wherein the back of the frame comprises a cutout portion for a camera lens of the portable electronic device.

13. The device according to claim 10, wherein the frame has a bottom, and wherein the bottom of the frame comprises a cutout portion for a charging receptacle of the portable electronic device.

14. The device according to claim 10, wherein the frame has a top, and wherein the top of the frame comprises a cutout portion for an on/off switch of the portable electronic device.

15. The device according to claim 10, wherein the device comprises at least one handle.

16. The device according to claim 10, wherein the frame has a back, and wherein the back of the frame comprises a support member.

17. The device according to claim 10, wherein the frame has a back, and wherein the back of the frame does not comprise a support member.

18. The device according to claim 11, wherein the frame has a back, and wherein the back of the frame comprises a cutout portion for a camera lens of the portable electronic device, wherein the frame has a bottom, and wherein the bottom of the frame comprises a cutout portion for a charging receptacle of the portable electronic device, wherein the frame has a top, and wherein the top of the frame comprises a cutout portion for an on/off switch of the portable electronic device, and wherein the edge is less than 7 mm in width.
